(19) United States
(12) Patent Application Publication
(10) Pub. No.: US 2026/0188607 A1
(43) Pub. Date: Jul. 2, 2026

(54) FOCUSED ION BEAM DEVICE AND METHOD OF PRODUCING A SAMPLE PIECE USING THE SAME

(71) Applicant: Samsung Electronics Co., Ltd., Suwon-si (KR)

(72) Inventors: YEOSEON CHOI, Suwon-si (KR); JAEGEUM YOON, Suwon-si (KR)

(21) Appl. No.: 19/246,153

(22) Filed: Jun. 23, 2025

(30) Foreign Application Priority Data
Dec. 30, 2024 (KR) 10-2024-0201016

(51) Int. Cl. H01J 37/20; H01J 37/06; H01J 37/08

(52) U.S. Cl. CPC H01J 37/20; H01J 37/06; H01J 37/08; H01J 2237/204; H01J 2237/2802

(57) ABSTRACT

A focused ion beam device includes a chamber, a stage in the chamber, an electron beam generator in the chamber and emitting an electron beam toward a sample on the stage, an ion beam generator in the chamber and emitting an ion beam toward the sample on the stage, a detector in the chamber and detecting secondary electrons emitted from the sample, and a first loader and a second loader connected to the chamber.

### CROSS-REFERENCE TO RELATED APPLICATIONS

This U.S. non-provisional patent application claims priority under 35 U.S.C.§119 to Korean Patent Application No. 10-2024-0201016 filed on December 30, 2024, in the Korean Intellectual Property Office, the entire contents of which are hereby incorporated by reference.

### BACKGROUND OF THE INVENTION

The inventive concept relates to a focused ion beam device and a method of producing an analysis sample using the same. More specifically, the inventive concept relates to a focused ion beam device including a plurality of loaders and a method of producing an analysis sample using the same.

To observe a sample of a semiconductor wafer, various devices are utilized. For example, a cross-section of a sample of a semiconductor wafer may be observed through a transmission electron microscope (TEM). A production of an analysis sample for producing a sample required for TEM analysis may be performed separately. For example, the production of an analysis sample may be performed through a focused ion beam device. The process of producing the analysis sample using a focused ion beam device takes a considerable amount of time. Various studies are being conducted to reduce the time required for producing an analysis sample using the focused ion beam device.

### SUMMARY

An object of the inventive concept is to provide a focused ion beam device capable of reducing idle time and, a method of producing an analysis sample using the same.

An object of the inventive concept is to provide a focused ion beam device with improved productivity and efficiency, and a method of producing an analysis sample using the same.

The problem to be solved by the inventive concept is not limited to the problems mentioned above, and other problems not mentioned may be clearly understood by those skilled in the art from the description below.

According to an aspect of the present disclosure, a focused ion beam device may include a chamber, a stage in the chamber, an electron beam generator in the chamber and emitting an electron beam toward a sample on the stage, an ion beam generator in the chamber and emitting an ion beam toward the sample on the stage, a detector in the chamber and detecting secondary electrons emitted from the sample, and a first loader and a second loader connected to the chamber.

According to an aspect of the present disclosure, a focused ion beam device may include a chamber provided with an electron beam generator, an ion beam generator, and a detector, and a first loader connected to the chamber, a second loader connected to the chamber, wherein the first loader is configured to load a first holder for fixing a sample, and the second loader is configured to load a second holder for fixing a grid.

According to an aspect of the present disclosure, for a method of producing an analysis sample may include loading a first sample on a first loader of a focused ion beam device, loading a first grid on a second loader of the focused ion beam device, moving the first sample from the first loader into a chamber of the focused ion beam device, performing a sampling process on the first sample to extract a first sample piece from the first sample, moving the first grid from the second loader into the chamber, fixing the first sample piece to the first grid, and performing a milling process on the first sample piece.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view illustrating a focused ion beam device according to a comparative example of the inventive concept.

FIG. 2 is a flowchart illustrating a substrate processing and substrate analysis method according to a comparative example of the inventive concept.

FIG. 3 is a flowchart illustrating a sample analysis method according to a comparative example of the inventive concept.

FIGS. 4, 5, and 6 are plan views illustrating a focused ion beam device for explaining a method of preparing an analysis sample according to a comparative example of the inventive concept.

FIG. 7 is a flowchart illustrating a method of analyzing a sample according to some embodiments of the inventive concept.

FIG. 8 is a flowchart illustrating a method of preparing an analysis sample according to some embodiments of the inventive concept.

FIG. 9 is a flowchart illustrating a method of analyzing a sample according to some embodiments of the inventive concept.

FIG. 10 is a flowchart illustrating a method of preparing an analysis sample according to some embodiments of the inventive concept.

FIGS. 11, 12, 13, and 14 are plan views illustrating a focused ion beam device for explaining a method of preparing an analysis sample according to some embodiments of the inventive concept.

FIGS. 15, 16, 17, 18, 19, and 20 are plan views illustrating a focused ion beam device according to some embodiments of the inventive concept.

### DETAILED DESCRIPTION

Hereinafter, to explain the inventive concept specifically, embodiments according to the inventive concept will be described with reference to the attached drawings.

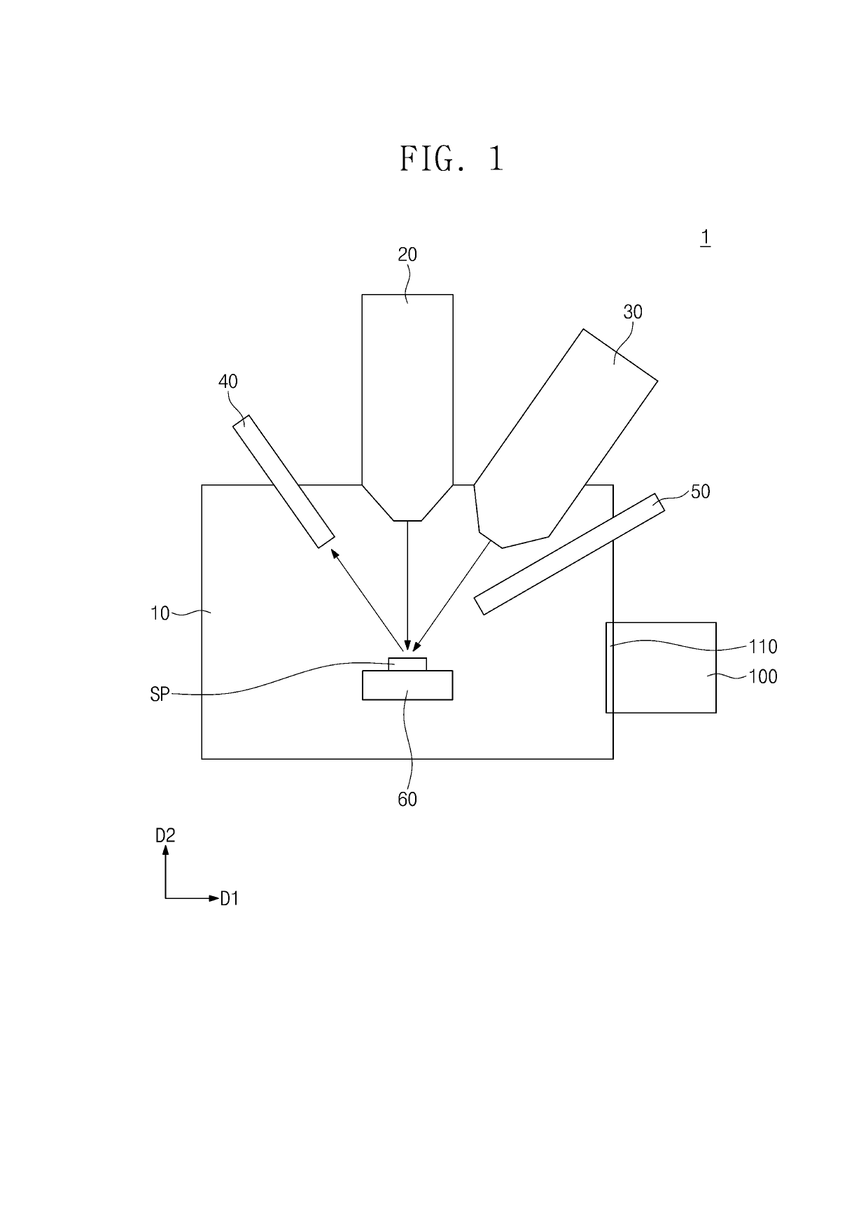

FIG. 1 is a cross-sectional view illustrating a focused ion beam device according to a comparative example of the inventive concept.

Referring to FIG. 1, a focused ion beam device 1 may perform a role of producing an analysis sample for transmission electron microscope (TEM) analysis. The focused ion beam device 1 may include a chamber 10, an electron beam device 20 (i.e., an electron beam generator), an ion beam device 30 (i.e., an ion beam generator), a detector 40, a gas supply 50, a stage 60, a loader 100, and a door 110 that are perform the role.

The chamber 10 may provide a space for producing an analysis sample. For example, an interior of the chamber 10 may be maintained in a high vacuum state.

The electron beam device 20 may be provided inside the chamber 10. The electron beam device 20 may emit an electron beam toward a sample SP provided on the stage 60 described later in the chamber 10. The electron beam emitted from the electron beam device 20 may be irradiated to the sample SP, and thus, secondary electrons may be emitted from the sample SP.

Although not shown in the drawing, the electron beam device 20 may include a source unit, an acceleration unit, and a lens unit therein. Electrons may be generated from the source unit, and an electron beam may be formed by accelerating the electrons through the acceleration unit. The electron beam may be focused through the lens unit.

The ion beam device 30 may be provided in the chamber 10. The ion beam device 30 may emit an ion beam toward the sample SP provided on the stage 60 described later in the chamber 10. The ion beam emitted from the ion beam device 30 may be irradiated to the sample SP. Accordingly, a portion of the sample SP may be etched through the ion beam. For example, the ion beam device 30 may generate a focused beam of Ga⁺ ions to physically sputter material away through momentum transfer. A role of the ion beam device 30 will be described in detail when explaining the method of producing an analysis sample, which will be described later.

Although not shown in the drawing, the ion beam device 30 may include a source unit, an acceleration unit, and a lens unit therein. Ions may be generated from the source unit, and an ion beam may be formed by accelerating the ions through the acceleration unit. The ion beam may be focused through the lens unit. As an example, the source provided to the source unit may include gallium (Ga).

The detector 40 may be provided in the chamber 10. The detector 40 may detect the secondary electrons emitted from a surface of the sample SP during a time when the surface of the sample SP is illuminated by an electron beam generated from the electron beam device 20 and may serve to generate an image of the surface of the sample SP.

The gas supply 50 may be provided in the chamber 10. The gas supply 50 may be arranged adjacent to the stage 60 described later. For example, the gas supply 50 may serve to supply a source gas for forming a protective layer that protects the surface of the sample SP.

The stage 60 may be provided in the chamber 10. The stage 60 may serve to fix the sample SP to produce an analysis sample. Although not shown in the drawing, for example, the stage 60 may move in horizontal and vertical directions. In this specification, the horizontal direction may be parallel to a bottom surface (i.e., a floor of a facility in which the focused ion beam is installed) on which the focused ion beam device is installed. In this specification, the vertical direction may be perpendicular to the bottom surface on which the focused ion beam device is installed. A first direction D1 shown in the drawing refers to one direction of the horizontal direction, and a second direction D2 refers to the vertical direction.

The loader 100 may be provided on a sidewall of the chamber 10. The loader 100 may serve as a passage for moving the sample SP from the outside of the focused ion beam device 1 into the chamber 10, or for moving the sample SP from the inside of the chamber 10 to the outside of the focused ion beam device 1. The door 110 may be provided between the loader 100 and the chamber 10. When the door 110 is opened, the loader 100 may be in communication with the chamber 10. For example, as shown in the drawing, the focused ion beam device 1 according to the comparative example of the inventive concept may be equipped with a single loader 100 for loading or unloading the sample SP.

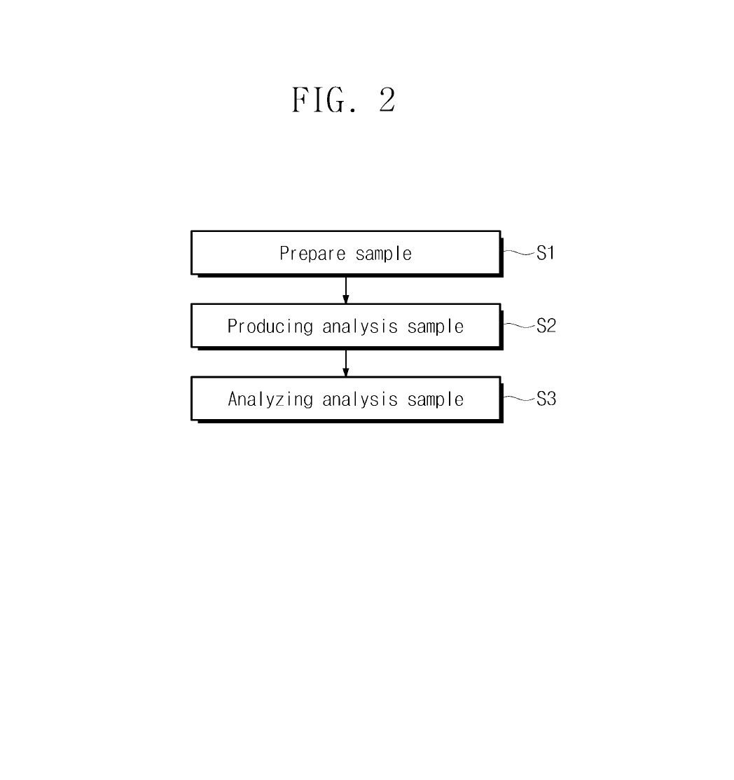

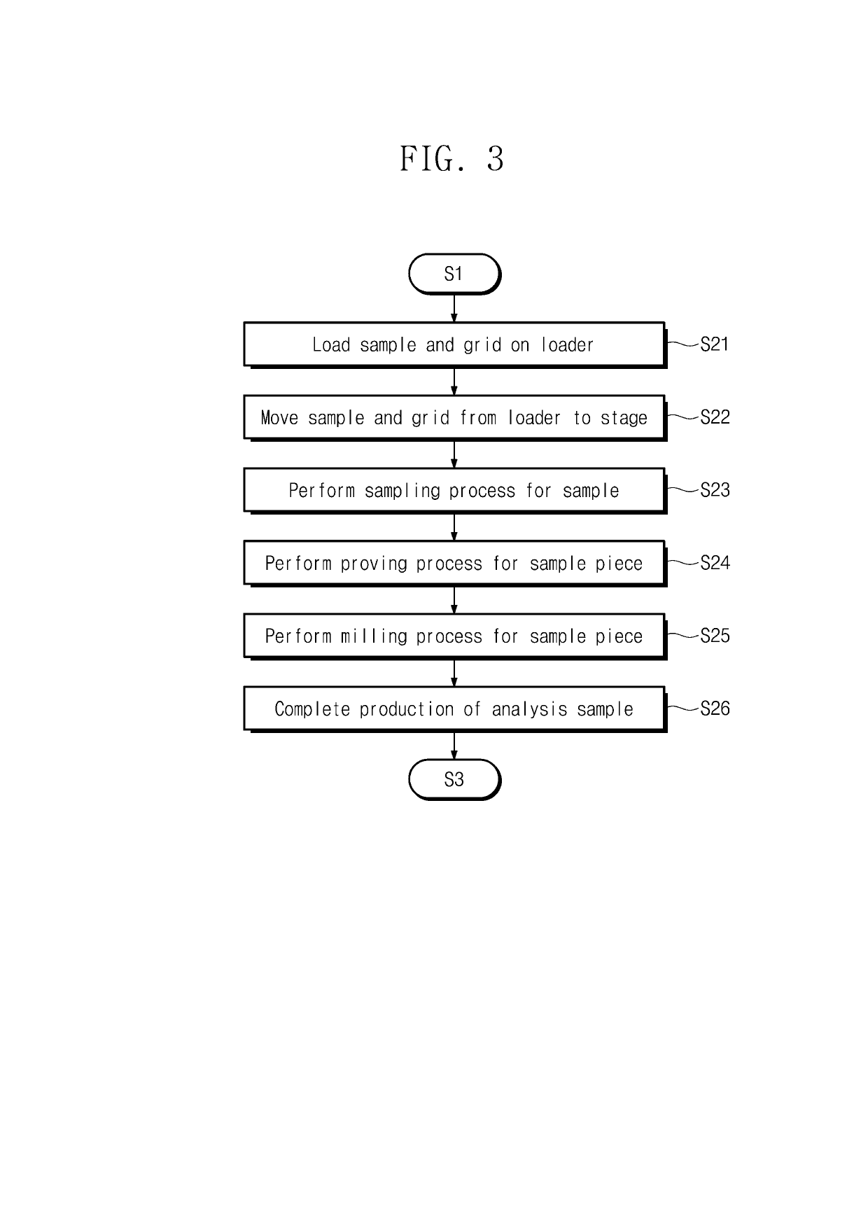

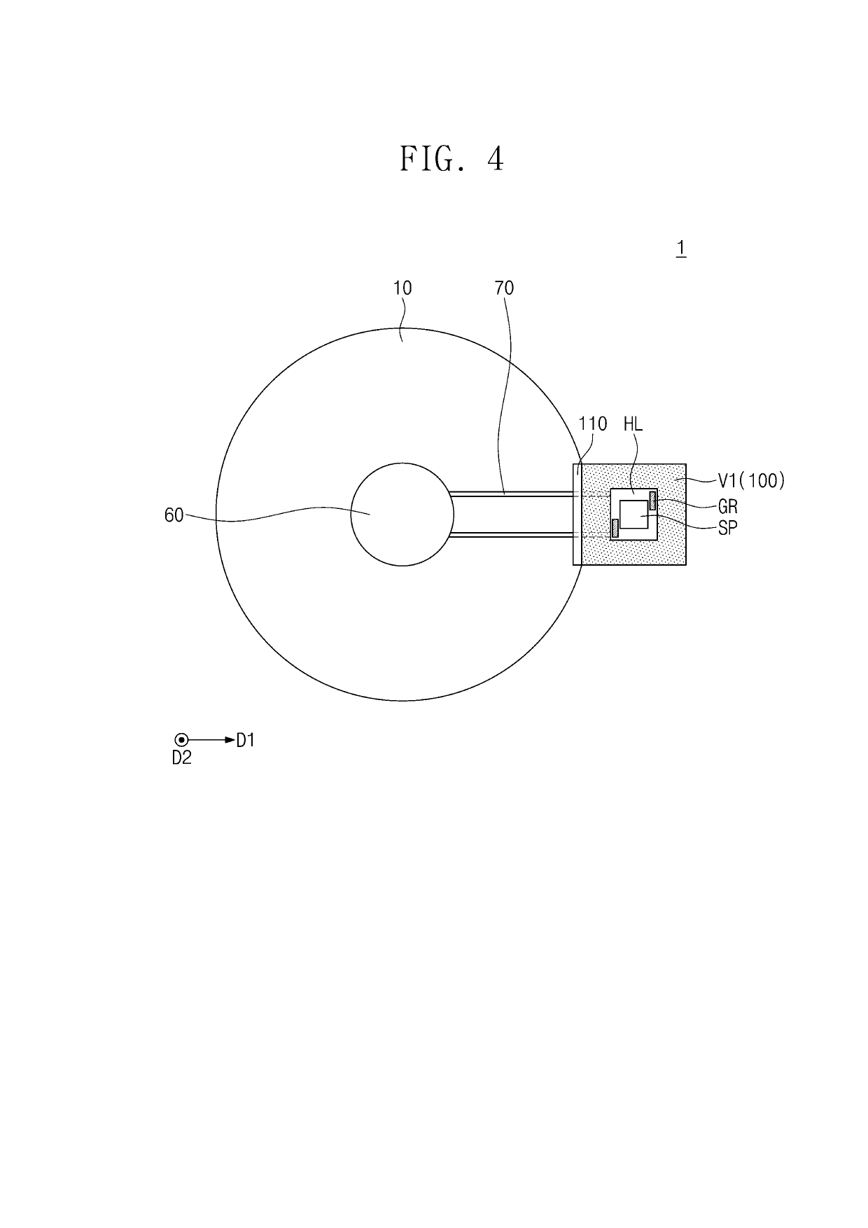

FIG. 2 is a flowchart illustrating a substrate processing and substrate analysis method according to a comparative example of the inventive concept. FIG. 3 is a flowchart illustrating a sample analysis method according to a comparative example of the inventive concept. FIGS. 4, 5, and 6 are plan views illustrating a focused ion beam device for explaining a method of preparing an analysis sample according to a comparative example of the inventive concept.

Referring to FIG. 2, a sample analysis method according to the comparative example of the inventive concept may include preparing a sample in S1, producing an analysis sample in S2, and analyzing the analysis sample in S3.

The preparing of the sample in S1 may include preparing a substrate that has undergone portion or all of a semiconductor manufacturing process and extracting a portion of the substrate. Here, the preparing of the substrate that has undergone the portion or all of the semiconductor manufacturing process may include preparing a semiconductor wafer that has undergone a photo process, a deposition process, or a development process. Here, the extracting of the portion of the substrate may include slicing a portion of the substrate to be analyzed from the substrate. The sample may mean a portion of the sliced substrate.

The producing of the analysis sample in S2 may include producing an analysis sample from the prepared sample through the focused ion beam device 1. The analyzing of the analysis sample in S3 may include analyzing the produced analysis sample through a TEM analysis device.

Hereinafter, with reference to FIGS. 3 to 6, the producing of the analysis sample in S2 according to a comparative example of the inventive concept among the steps S1, S2, and S3 described above will be described in detail. First, the focused ion beam device 1 described with reference to FIG. 1 may further include a rail 70 and a manipulator 80.

Referring to FIGS. 3 and 4, the producing of the analysis sample in S2 may include loading a sample SP and a grid GR on a loader 100 in S21, moving the sample SP and the grid GR from the loader 100 to the stage 60 in S22, performing a sampling process for the sample SP in S23, performing a proving process for a sample piece Spa in S24 (i.e., attaching the sample piece Spa to the grid GR), performing a milling process for the sample piece Spa in S25, and completing the production of the analysis sample in S26.

In the loading of the sample SP and the grid GR on the loader 100 in S21, the door 110 may be closed, and an interior of the loader 100 may be in a vented state V1. The sample SP and the grid GR may be provided on a holder HL. The holder HL may serve to fix the sample SP and the grid GR. Each of the sample SP and the grid GR may be fixed to the holder HL outside the focused ion beam device 1. The loading of the sample SP and the grid GR on the loader 100 in S21 may include moving the holder HL to which the sample SP and the grid GR are fixed from the outside to the loader 100. Accordingly, the holder HL may be loaded on the loader 100, and thus the sample SP and the grid GR may be loaded on the loader 100.

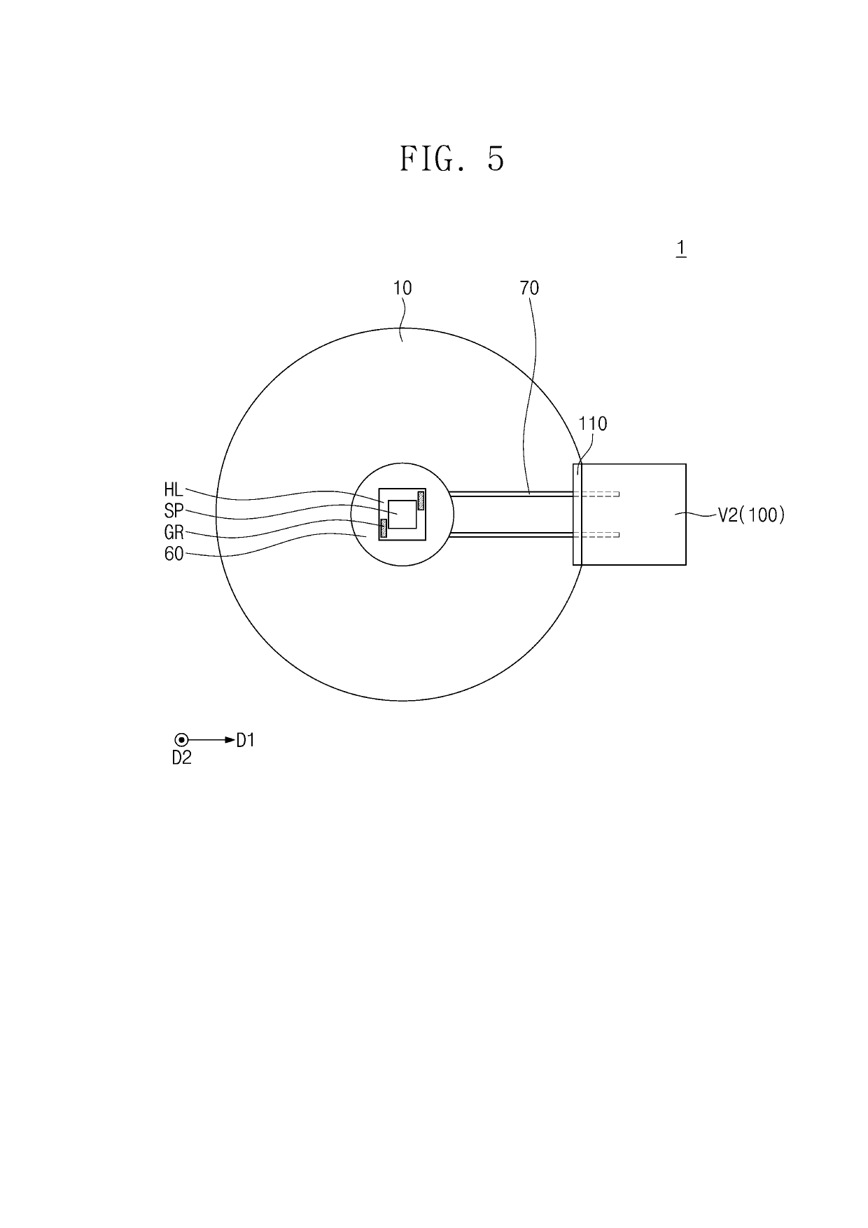

Referring to FIGS. 3 and 5, the moving of the sample SP and the grid GR from the loader 100 to the stage 60 in S22 may include evacuating an interior of the loader 100 a vacuum state V2, opening the door 110, and moving the holder HL from the loader 100 to the stage 60 via the rail 70.

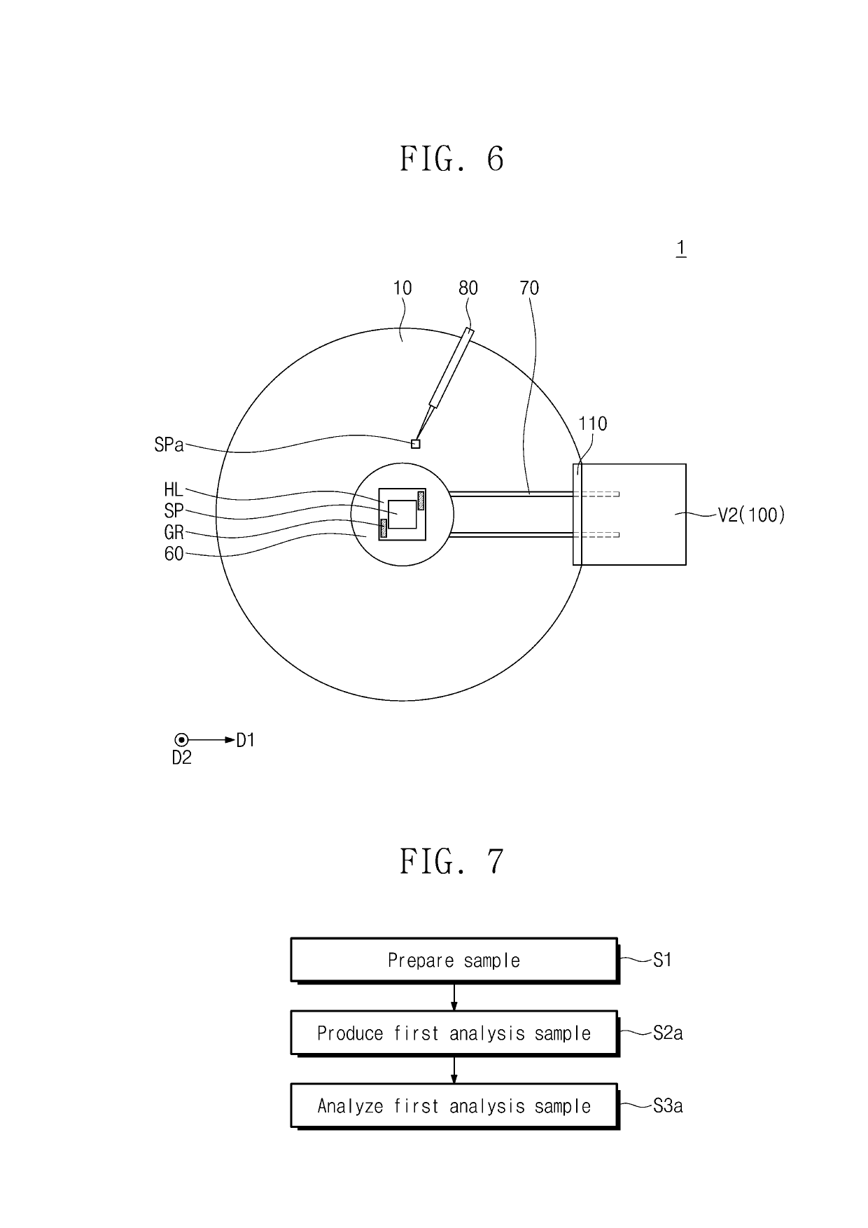

Referring to FIGS. 3 and 6, the performing of the sampling process for the sample SP in S23 may include extracting a sample piece SPa corresponding to the analysis sample. For example, extracting the sample piece SPa may include etching a portion of the sample SP through an ion beam device 30 and removing another portion of the sample SP corresponding to the sample piece SPa from the sample SP through a manipulator 80. In other words, the ion beam device 30 may cut a trench around a region of interest, and then the manipulator 80 may lift out the sample piece Spa from the sample SP. The sample piece may have a shape of a thin lamella. For example, when the sampling process is performed, a source gas may be supplied to the gas supply 50, thereby forming a protective layer on the upper surface of another portion of the sample SP corresponding to the sample piece SPa.

Thereafter, the proving process for the sample piece SPa in S24 (i.e., attaching of the sample piece Spa to the grid GR) may be performed. Thereafter, the performing of the proving process for the sample piece SPa in S24 may include holding the sample piece SPa via the manipulator 80, moving the sample piece SPa to the grid GR via the manipulator 80, and fixing the sample piece SPa to the grid GR via the manipulator 80. Although not shown in the drawing, the grid GR may include protrusions. The sample piece SPa may be fixed to the protrusions of the grid GR.

Then, the milling process for the sample piece SPa in S25 may be performed. The performing of the milling process for the sample piece SPa in S25 may include performing an etching process for a portion of the sample piece SPa fixed to the grid GR. The etching process may be performed using an ion beam device 30. For example, the ion beam device 30 may generate a focused beam of Ga⁺ ions to physically sputter material away through momentum transfer. A thickness of the sample piece SPa may be reduced through the etching process. After the etching process is completed, the thickness of the sample piece SPa may mean an appropriate thickness of the sample piece SPa that may perform TEM measurement.

Thereafter, although not shown in the drawing, the holder HL may be moved from the stage 60 to the loader 100 through the rail 70. After the door 110 is closed, an interior of the loader 100 may be evacuated to the vented state V1 as described with reference to FIG. 4. Thereafter, the holder HL may be unloaded from the loader 100, and the producing of the analysis sample may be completed in S26.

The focused ion beam device 1 may have a lot of idle time when the producing of the analysis sample in S2 according to the comparative example of the inventive concept is performed. This is because the focused ion beam device 1 includes only one loader 100. In detail, one holder HL including the sample SP and the grid GR may be loaded on one loader 100 and moved along a rail 70 to a stage 60. When the sample SP or the grid GR is replaced during the sampling process in S23, the proving process in S24, and the milling process in S25 described above, the holder HL should be moved to the outside through one loader 100. While a new sample SP or a new grid GR is fixed to the holder HL from the outside, and the holder HL is loaded on the loader 100 and moved to the stage 60, the focused ion beam device 1 may have unnecessary idle time. As a result, productivity of preparing the analysis sample S2 may be reduced in the focused ion beam device 1 according to the comparative example of the inventive concept and the method of producing the analysis sample in S2 using the same.

To solve the above problems, the focused ion beam device 1 and the method of producing the analysis sample in S2a and S2b using the same according to some embodiments of the inventive concept will be described below with reference to FIGS. 7 to 14.

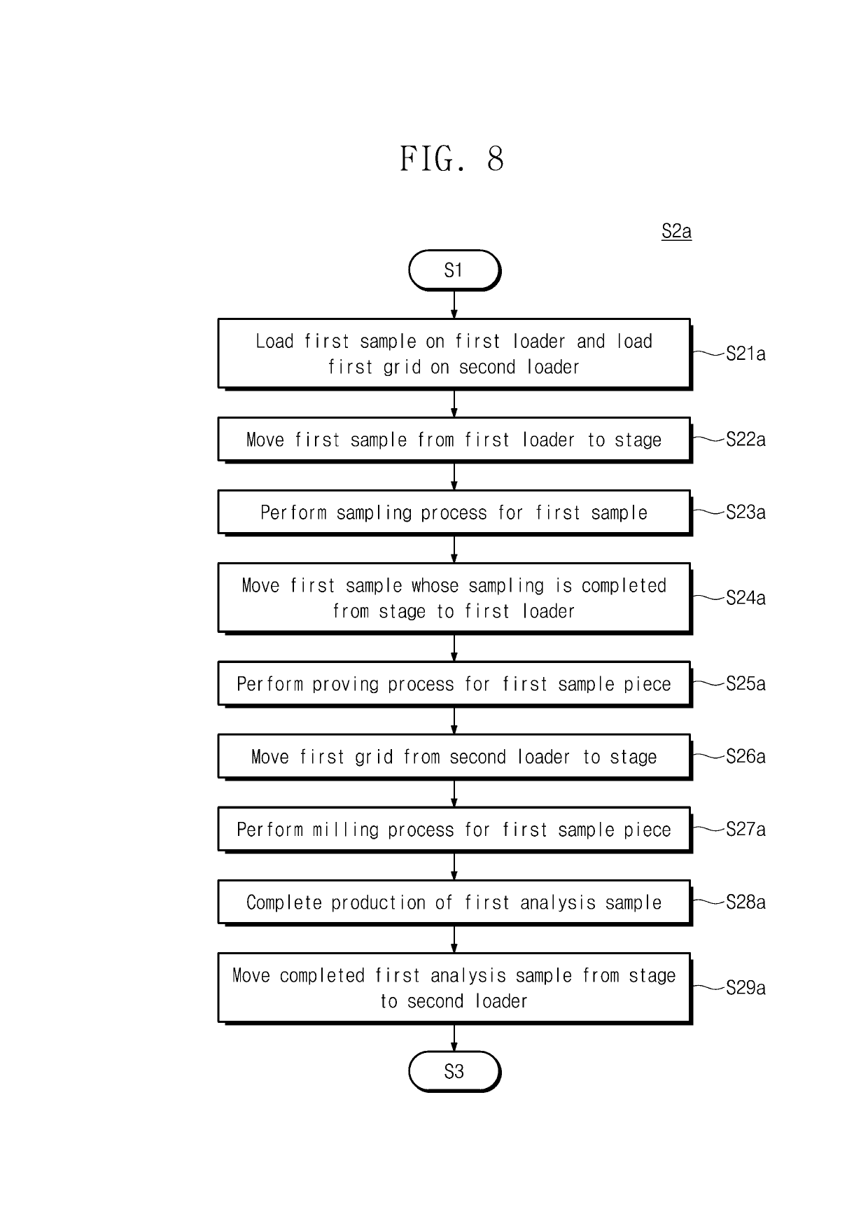

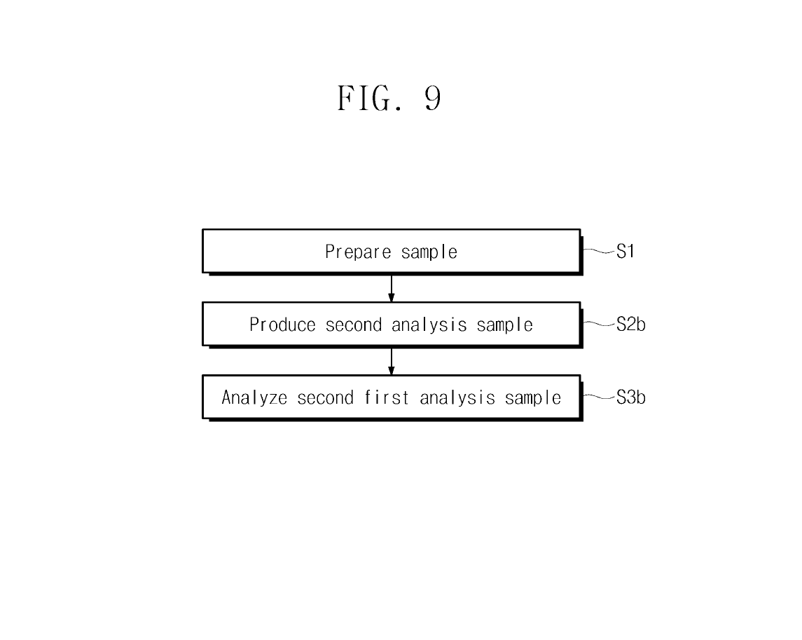

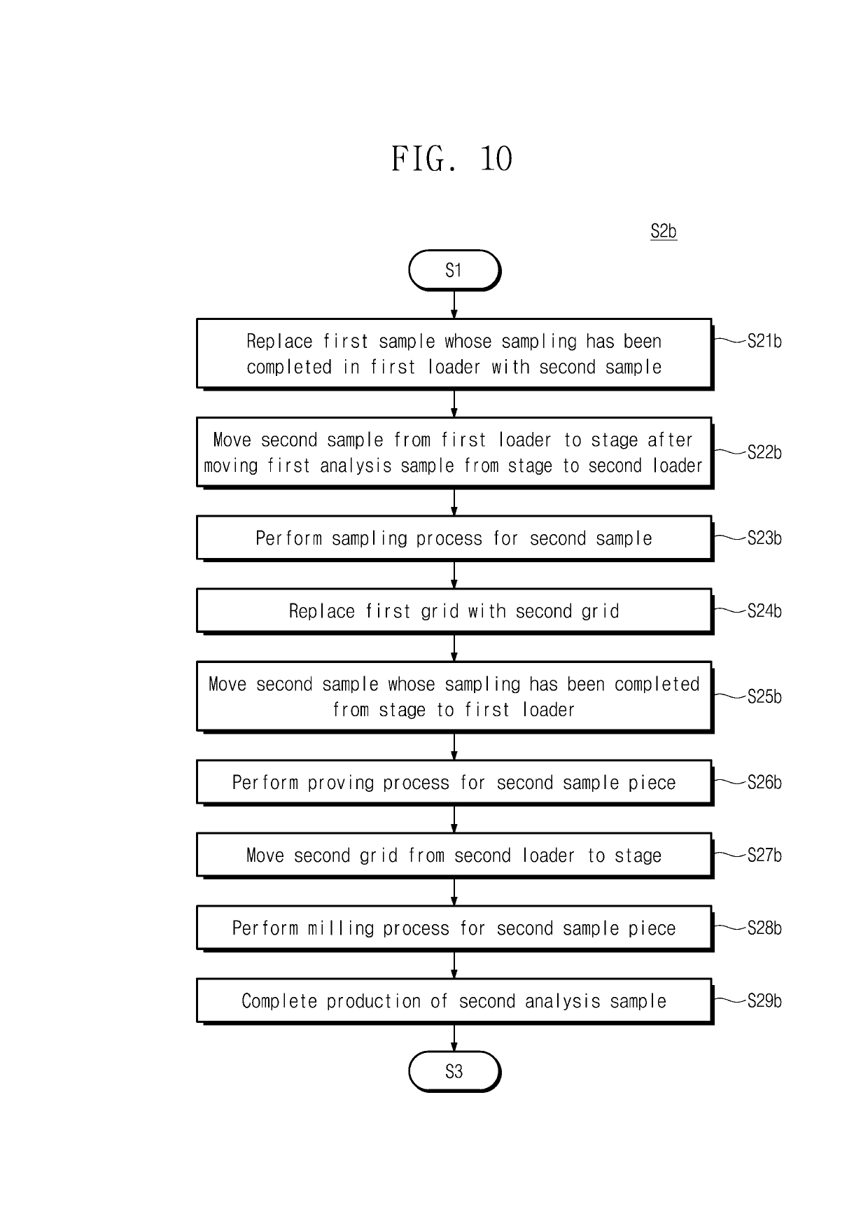

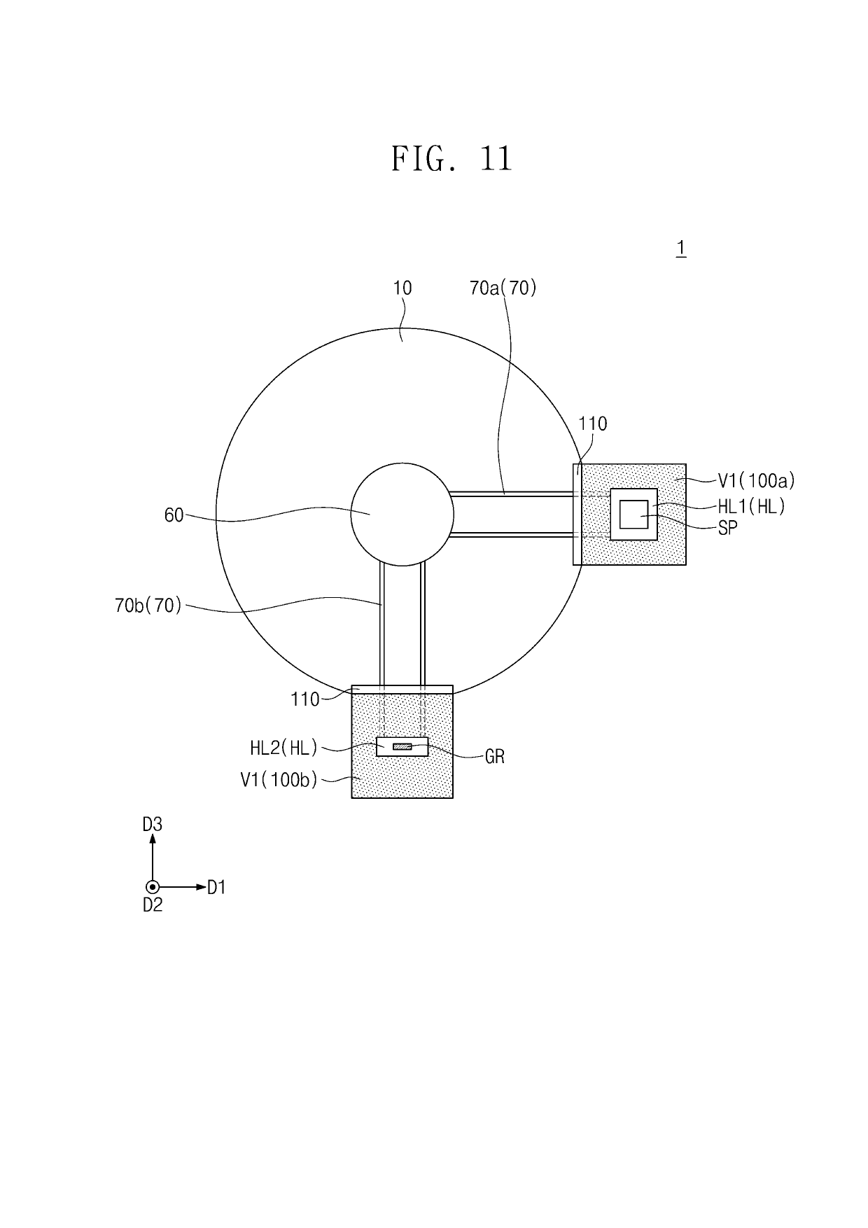

FIG. 7 is a flowchart illustrating a method of analyzing a sample according to some embodiments of the inventive concept. FIG. 8 is a flowchart illustrating a method of preparing an analysis sample according to some embodiments of the inventive concept. FIG. 9 is a flowchart illustrating a method of analyzing a sample according to some embodiments of the inventive concept. FIG. 10 is a flowchart illustrating a method of preparing an analysis sample according to some embodiments of the inventive concept. FIGS. 11, 12, 13, and 14 are plan views illustrating a focused ion beam device for explaining a method of preparing an analysis sample according to some embodiments of the inventive concept.

Referring to FIG. 7, a sample analysis method according to some embodiments of the inventive concept may include preparing a sample in S1, producing a first analysis sample in S2a, and analyzing the first analysis sample in S3a.

The preparing of the sample in S1 and the analyzing of the first analysis sample in S3a may be the same as/similar to the preparing of the sample in S1 and the analyzing of the analysis sample in S3 described with reference to FIG. 2. In contrast, the preparing of the first analysis sample in S2a may be different from the preparing of the analysis sample in S2 described with reference to FIG. 2. The difference will be described in detail below.

Referring to FIG. 8 and FIGS. 11 to 13, unlike the focused ion beam device 1 described with reference to FIG. 1, a focused ion beam device 1 according to some embodiments of the inventive concept may include a plurality of loaders 100a and 100b. For example, the plurality of loaders 100a and 100b may include a first loader 100a and a second loader 100b that are arranged to be spaced apart from each other. In the drawing, two loaders 100a and 100b are illustrated, but are not limited thereto.

Unlike what was described with reference to FIG. 4, a holder HL may include a plurality of holders HL1 and HL2. For example, the holder HL may include a first holder HL1 loaded on the first loader 100a and the second holder HL2 loaded on a second loader 100b. Unlike the comparative example of the inventive concept in which both a sample SP and a grid GR are fixed to the same holder HL, the sample SP may be fixed to the first holder HL1 and the grid GR may be fixed to the second holder HL2 separated from the first holder HL1. For example, the sample SP and the grid GR may be fixed to different holders HL, respectively, and may be loaded to different loaders 100a and 100b, respectively. The sample SP illustrated in FIG. 11 is referred to as a first sample, and the grid GR is referred to as a first grid.

Unlike what was described with reference to FIG. 4, a rail 70 may include a plurality of rails 70a and 70b. For example, the rail 70 may include a first rail 70a between the first loader 100a and the stage 60, and a second rail 70b between the second loader 100b and the stage 60. The first rail 70a may extend in the first direction D1, and a second rail 70b may extend in a third direction D3. The third direction D3 may be a direction different from the first direction D1. The first rail 70a may connect the first loader 100a and the stage 60 with each other, and the second rail 70b may connect the second loader 100b and the stage 60 with each other.

The producing of the first analysis sample in S2a may include loading the first sample SP on the first loader 100a and loading the first grid GR on the second loader 100b in S21a, moving the first sample SP from the first loader 100a to the stage 60 in S22a, performing a sampling process for the first sample SP in S23a, moving the first sample SP whose sampling is completed from the stage 60 to the first loader 100a in S24a, performing a proving process for the first sample piece Spa (i.e., attaching the first sample piece Spa to the first grid GR) in S25a, moving the first grid GR from the second loader 100b to the stage 60 in S26a, performing a milling process for the first sample piece Spa in S27a, completing the production of the first analysis sample in S28a, and moving the completed first analysis sample from the stage 60 to the second loader 100b in S29a.

First, referring to FIGS. 8 and 11, when the loading of the first sample SP on the first loader 100a and the loading of the first grid GR on the second loader 100b in S21a are performed, an interior of each of the first loader 100a and the second loader 100b may be in a vented state in V1.

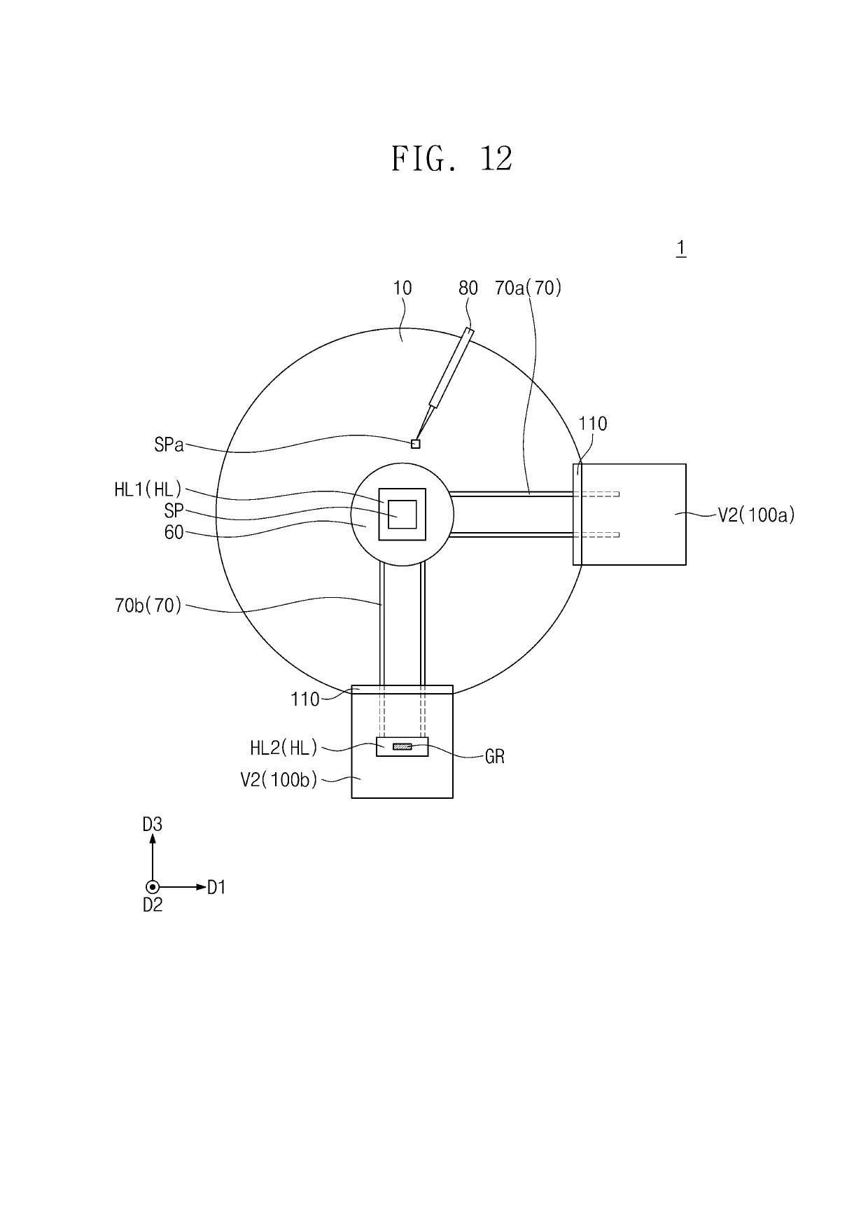

Hereinafter, referring to FIGS. 8 and 12, the moving of the first sample SP from the first loader 100a to the stage 60 in S22a may include evacuating the interior of the first loader 100a to a vacuum state V2, opening the door 110, and moving the first holder HL1 from the first loader 100a to the stage 60 via the first rail 70a. For example, when evacuating the interior of the first loader 100a to the vacuum state V2, an interior of the second loader 100b may also be evacuated to the vacuum state V2, but is not limited thereto.

The performing of the sampling process for the first sample SP in S23a may be the same as/similar to the sampling process for the sample SP described with reference to FIG. 3 and FIG. 6. Unlike the comparative example of the inventive concept described with reference to FIG. 3, when the performing of the sampling process inside the chamber 10 in S23a is performed, the first grid GR may be loaded on the second loader 100b.

Thereafter, unlike the comparative example of the inventive concept described with reference to FIG. 3, after the sampling process for the first sample SP in S23a, the moving of the first sample SP whose sampling is completed from the stage 60 to the first loader 100a in S24a may be performed.

Thereafter, a portion of the proving process for the first sample piece Spa extracted through the sampling process for the first sample SP in S23a may be performed. For example, holding the first sample piece Spa through the manipulator 80 may be performed. The manipulator 80 may hold the first sample piece Spa until the first grid GR is introduced into the chamber 10 from the second loader 100b.

Thereafter, the moving of the first grid GR from the second loader 100b to the stage 60 in S26a may be performed, and the completing of the proving process for the first sample piece Spa may be performed. That is, fixing the first sample piece Spa to the first grid GR through the manipulator 80 may be performed.

Thereafter, the milling process for the first sample piece Spa in S27a may be performed. The milling process for the first sample piece Spa in S27a may be the same as/similar to the milling process for the sample piece Spa described with reference to FIG. 3 and FIG. 6. Unlike the comparative example of the inventive concept described with reference to FIG. 3, when the milling process is performed inside the chamber 10 in S27a, the first sample SP may be loaded from the stage 60 onto the first loader 100a or unloaded from the first loader 100a.

The performing of the milling process for the first sample piece Spa in S27a may be performed, and the producing of the first analysis sample may be completed in S28a. Moving the completed first analysis sample from the stage 60 to the second loader in S29a may be performed.

Referring to FIG. 9, a sample analysis method according to some embodiments of the inventive concept may include preparing a sample in S1, producing a second analysis sample in S2b, and analyzing the second analysis sample in S3b.

The preparing of the sample in S1 and the analyzing of the second analysis sample in S3b may be identical to the preparing of the sample in S1 and the analyzing of the analysis sample in S3 described with reference to FIG. 2. The preparing of the second analysis sample in S2b may be similar to the preparing of the first analysis sample in S2a. A portion of the preparing of the second analysis sample in S2b may be performed simultaneously with the preparing of the first analysis sample in S2a.

The producing of the second analysis sample in S2b may include replacing the first sample SP whose sampling has been completed in the first loader 100a with a second sample SPn in S21b, moving the first analysis sample whose production has been completed from the stage 60 to the second loader 100b in S29a, moving the second sample SPn from the first loader 100a to the stage 60 in S22b after the moving the first analysis sample that has been completed from the stage 60 to the second loader 100b in S29a, performing the sampling process for the second sample SPn in S23b, replacing the first grid GR with a second grid GRn in the second loader 100b in S24b, moving the second sample SPn whose sampling has been completed from the stage 60 to the first loader 100a in S25b, performing a proving process for a second sample piece SPb in S26b, moving the second grid GRn from the second loader 100b to the stage 60 in S27b, performing a milling process for the second sample piece SPb in S28b, and completing the production of a second analysis sample in S29b.

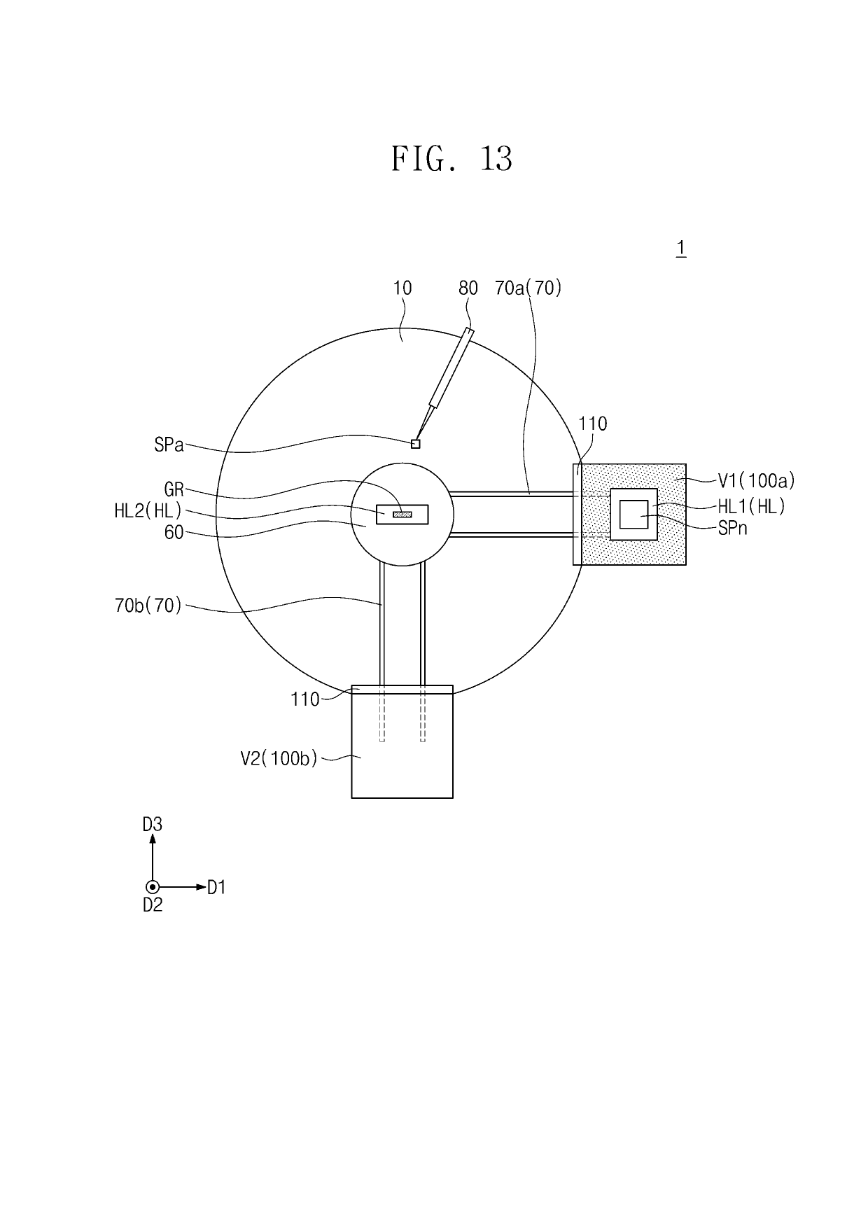

Referring to FIG. 10 and FIG. 13, the replacing of the first sample SP whose sampling has been completed in the first loader 100a with the second sample SPn in S21b may include evacuating an interior of the first loader 100a to a vented state V1, removing the first sample SP on the first holder HL1, fixing the second sample SPn on the first holder HL1, and loading the first holder HL1 back on the first loader 100a.

In the replacing of the first sample SP with the second sample SPn, the focused ion beam device 1 may perform an analysis sample producing process (e.g., the milling process for the first sample piece SPa in S27a) without idle time. That is, for example, during the proving process for the first sample piece Spa in S25a, the first sample SP may be moved to the first loader 100a in the chamber 10 and may be unloaded, and during the milling process for the first sample piece Spa in S27a, the first sample SP may be replaced with the second sample SPn.

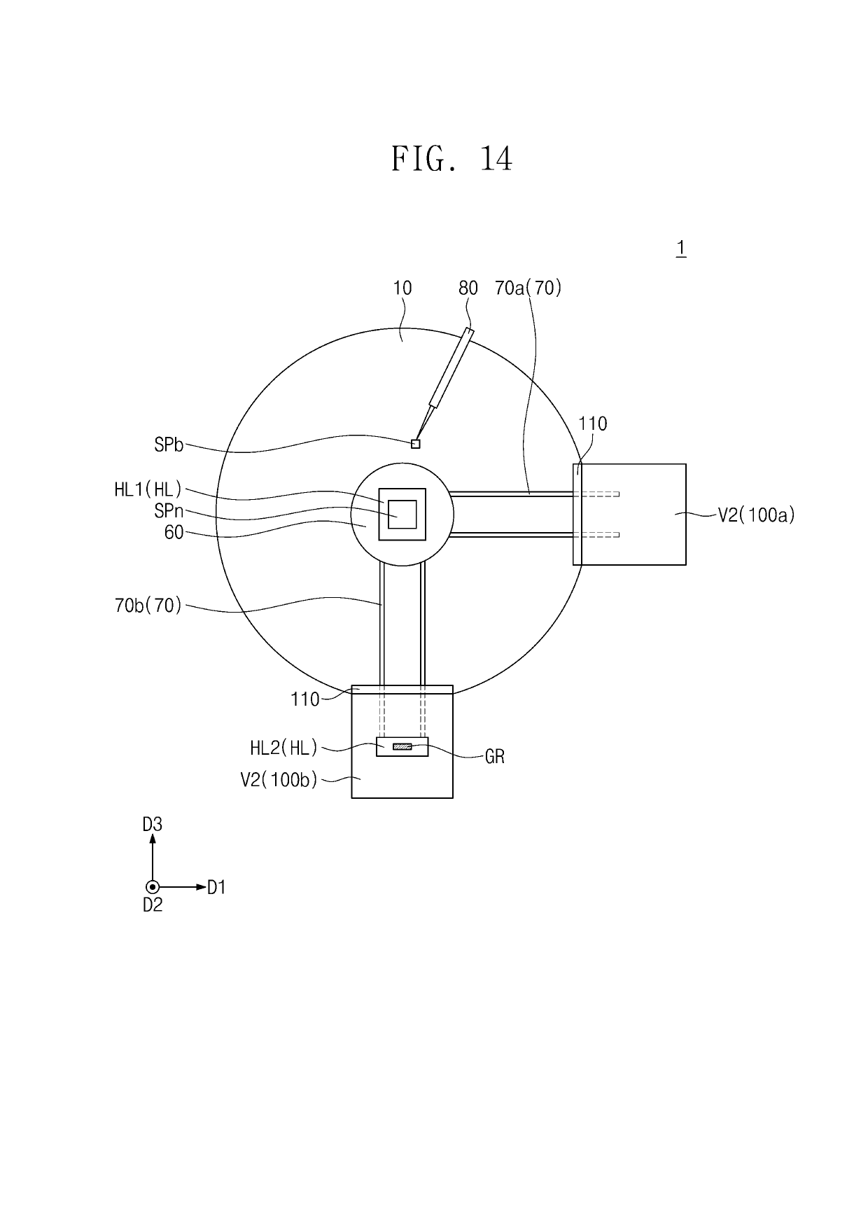

Referring to FIGS. 10 and 14, the first analysis sample may be moved from the stage 60 to the second loader 100b, and then the second sample SPn may be moved from the first loader 100a to the stage 60. Thereafter, the sampling process for the second sample SPn may be performed in S23b. The sampling process for the second sample SPn in S23b may be the same as/similar to the performing of the sampling process for the sample SP in S23 described with reference to FIGS. 3 and 6.

The replacing of the first grid GR with the second grid GRn in S24b may be performed during the sampling process for the second sample SPn in S24b, but is not limited thereto. For example, the step in S24b may be performed, before the sampling process for the second sample SPn in S23b and after moving the first analysis sample from the stage 60 to the second loader 100b, unlike as shown in the drawing.

In the process of replacing the first grid GR with the second grid GRn, the focused ion beam device 1 may perform preparing an analysis sample (e.g., the sampling process for the second sample SPn in S23b) without idle time.

Thereafter, a portion of the proving process for the second sample piece SPb extracted through the sampling process for the second sample SPn in S23b may be performed in S26b. That is, holding the second sample piece SPb through the manipulator 80 may be performed.

Thereafter, the moving of the second grid GRn from the second loader 100b to the stage 60 in S27b may be performed, and the completing of the proving process for the second sample piece SPb may be performed. That is, fixing the second sample piece SPb to the second grid GRn through the manipulator 80 may be performed.

Then, the milling process for the second sample piece SPb in S28b may be performed. The milling process for the second sample piece SPb in S28b may be the same as/similar to the milling process for the sample piece SPa described with reference to FIG. 3 and FIG. 6. By performing the milling process for the second sample piece SPb in S28b, the producing of the second analysis sample in S29b may be completed.

According to the inventive concept, the focused ion beam device 1 may include the first loader 100a and the second loader 100b. Accordingly, the first holder HL1 may be moved into the chamber 10 through the first loader 100a, and the second holder HL2 may be moved into the chamber 10 through the second loader 100b. For example, the first holder HL1 that fixes the sample SP and the second holder HL2 that fixes the grid GR may be moved independently. As a result, even when the sample SP is replaced with another sample, the focused ion beam device 1 may perform the producing of the analysis sample (e.g., the proving process or the milling process, etc.) without the idle time. In addition, even when the grid GR is replaced with another grid GR, the focused ion beam device 1 may perform the producing of the analysis sample (e.g., the sampling process) without the idle time. Therefore, productivity and efficiency of the focused ion beam device may be improved in the focused ion beam device 1 and the method of producing an analysis sample using the same.

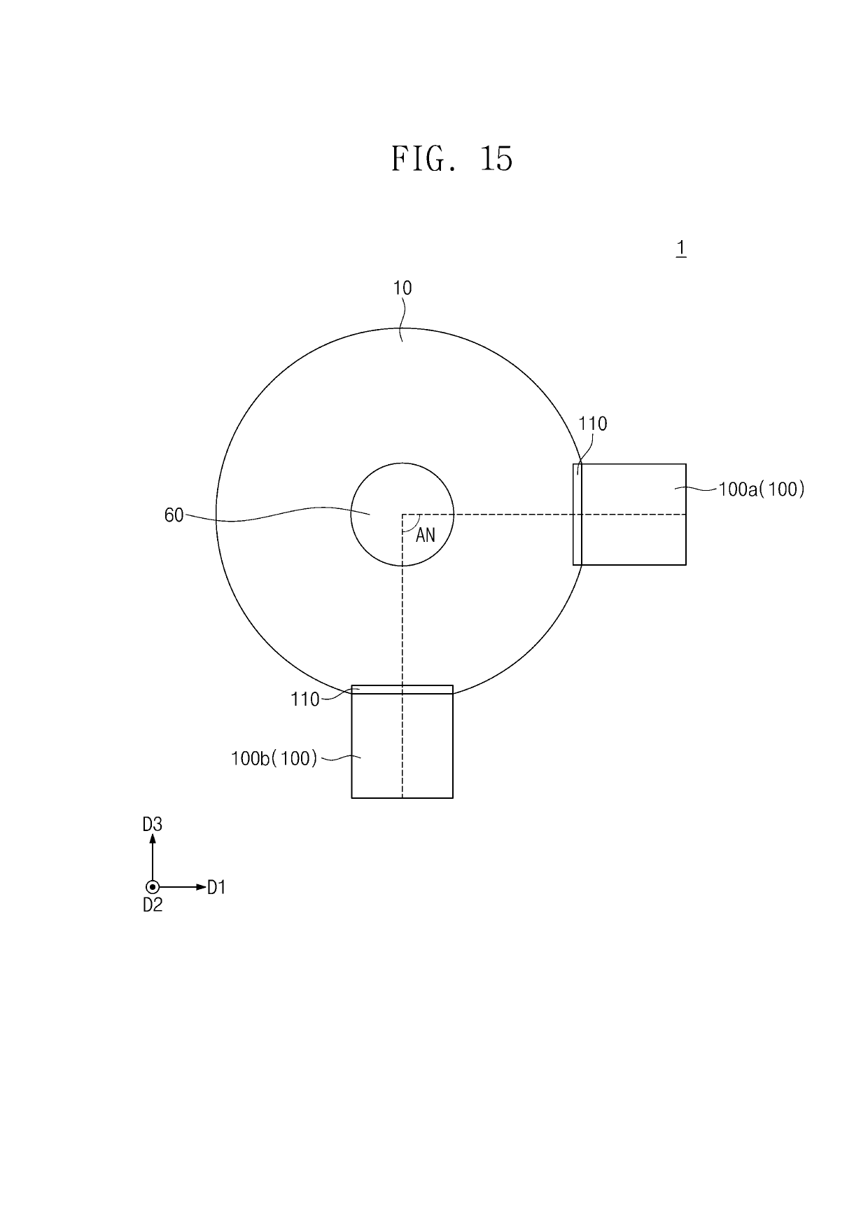

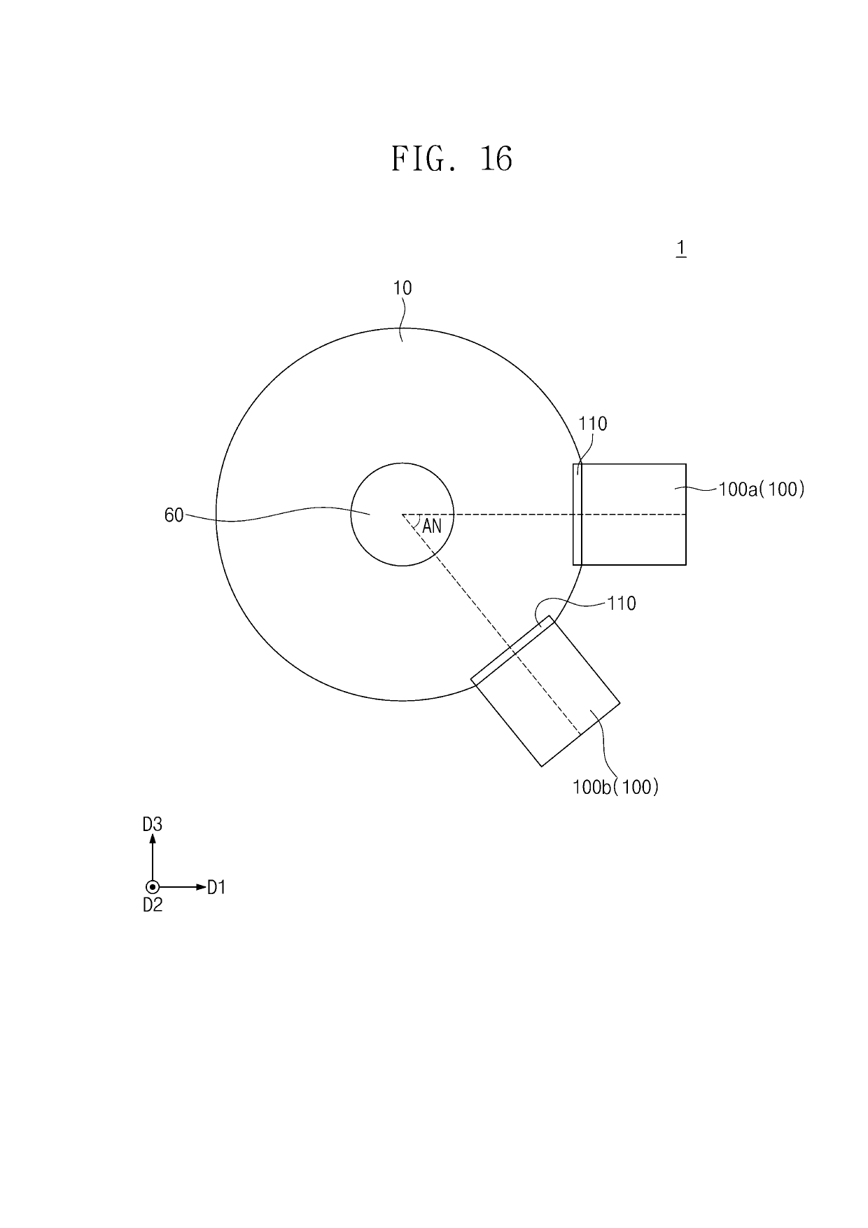

FIGS. 15, 16, 17, and 18 are plan views each illustrating a focused ion beam device according to some embodiments of the inventive concept.

Referring to FIGS. 15, 16, 17, and 18, an arrangement of the first loader 100a and the second loader 100b may be variously changed by a person skilled in the art.

Referring to FIG. 15, the first loader 100a and the second loader 100b may be arranged to be spaced apart from each other. For example, an angle AN between the first loader 100a and the second loader 100b may be 90°. In this specification, the angle AN between the first loader 100a and the second loader 100b may mean an imaginary angle formed by an imaginary line from a center of the first loader 100a to a center of the stage 60 and an imaginary line from a center of the second loader 100b to the center of the stage 60.

Referring to FIG. 16, the first loader 100a and the second loader 100b may be arranged to be spaced apart from each other. For example, the angle AN between the first loader 100a and the second loader 100b may be an acute angle.

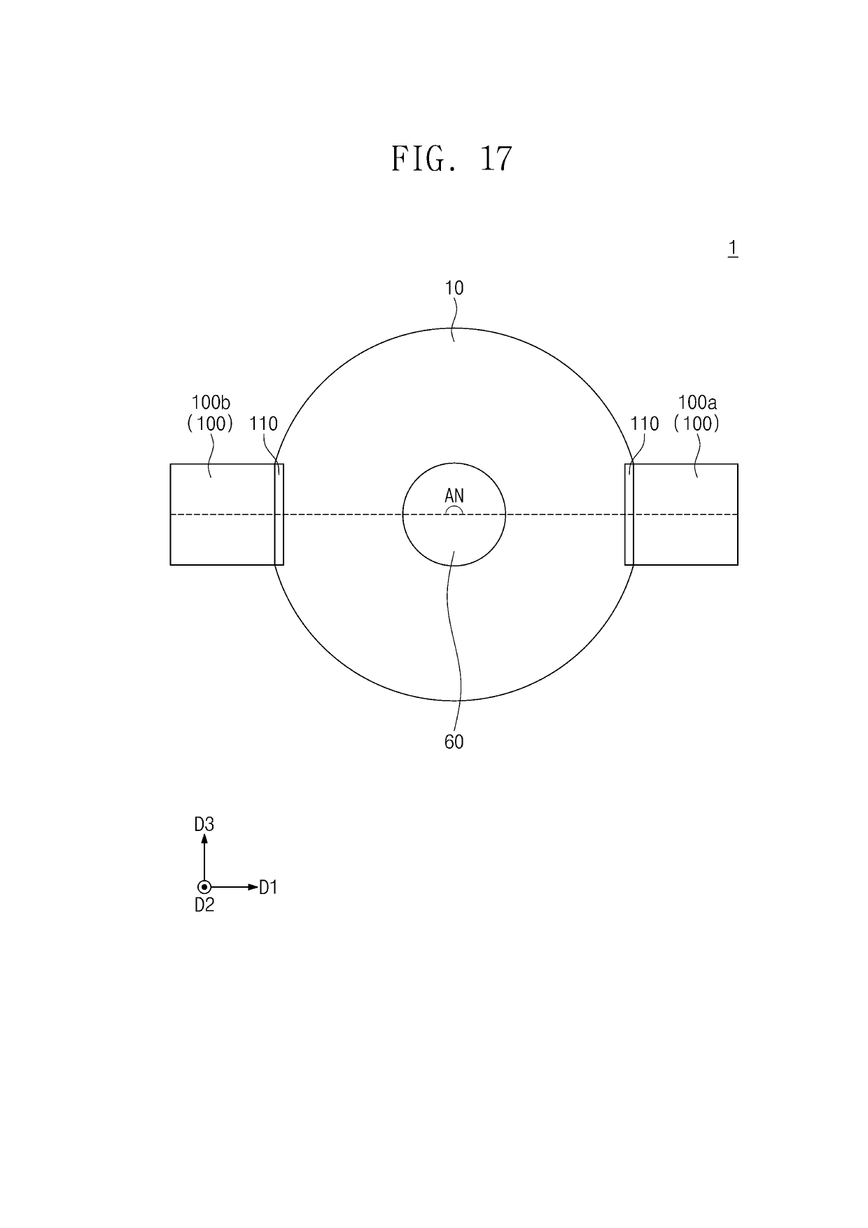

Referring to FIG. 17, the first loader 100a and the second loader 100b may be arranged to be spaced apart from each other. For example, the angle AN between the first loader 100a and the second loader 100b may be 180°.

The angle AN between the first loader 100a and the second loader 100b may be as described above, but is not limited thereto and may be variously changed by a person skilled in the art.

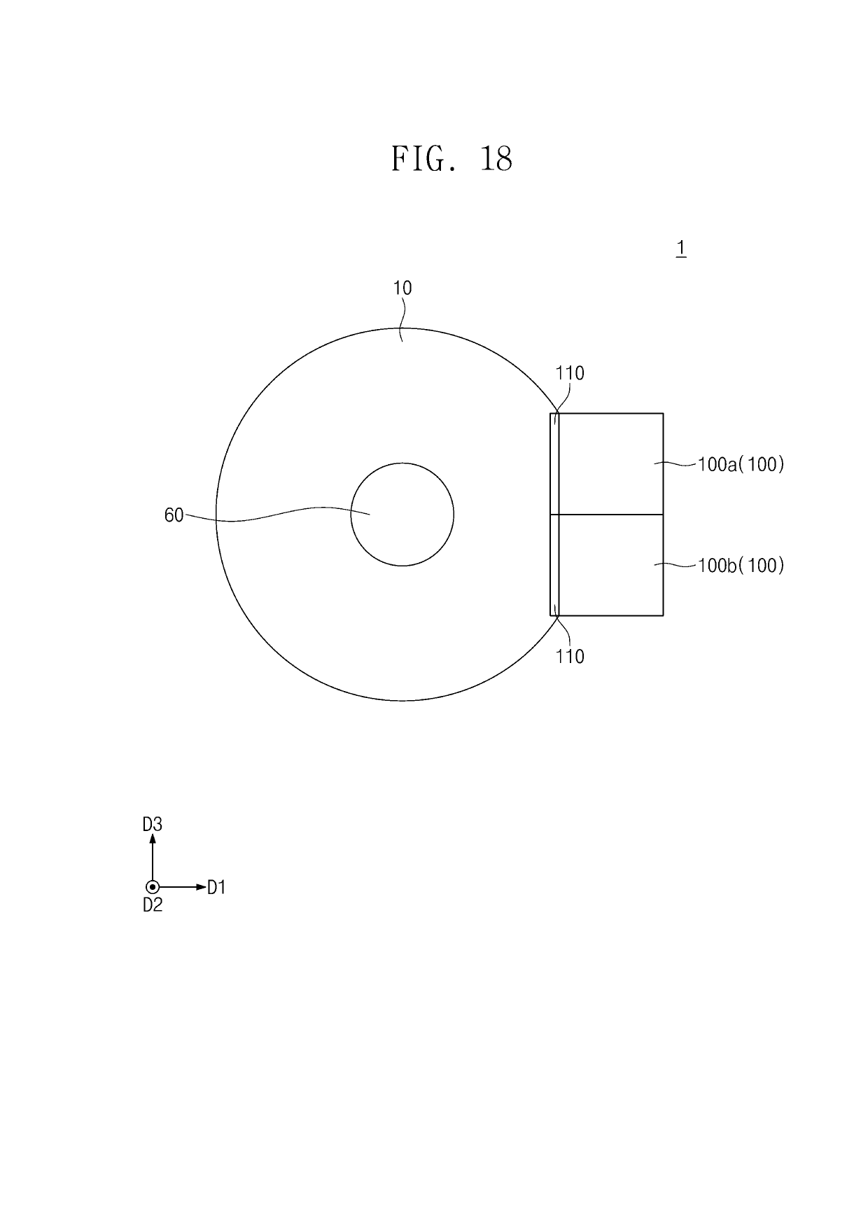

Referring to FIG. 18, the first loader 100a and the second loader 100b may be provided in one loader. However, a separate wall may exist between an internal space of the first loader 100a and an internal space of the second loader 100b, and accordingly, the internal space of the first loader 100a and the internal space of the second loader 100b may not be connected to each other in one loader.

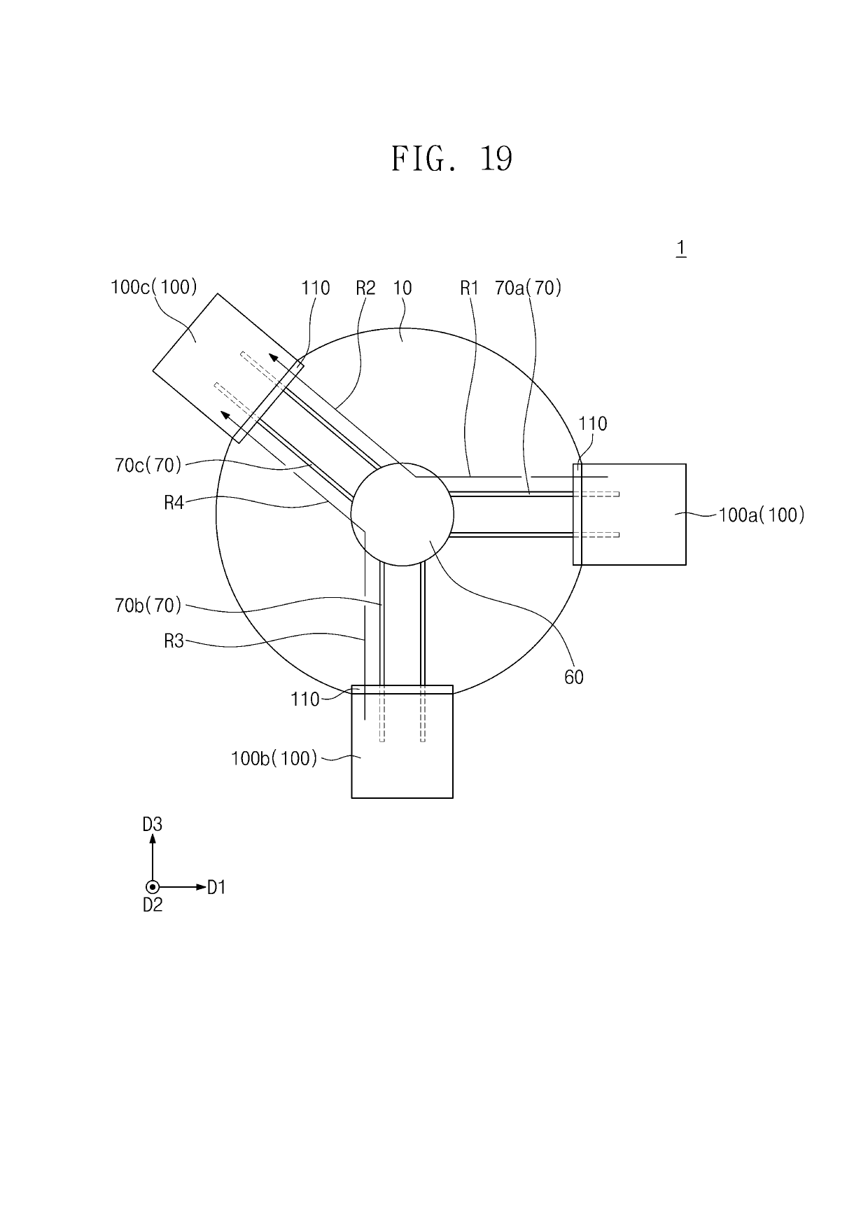

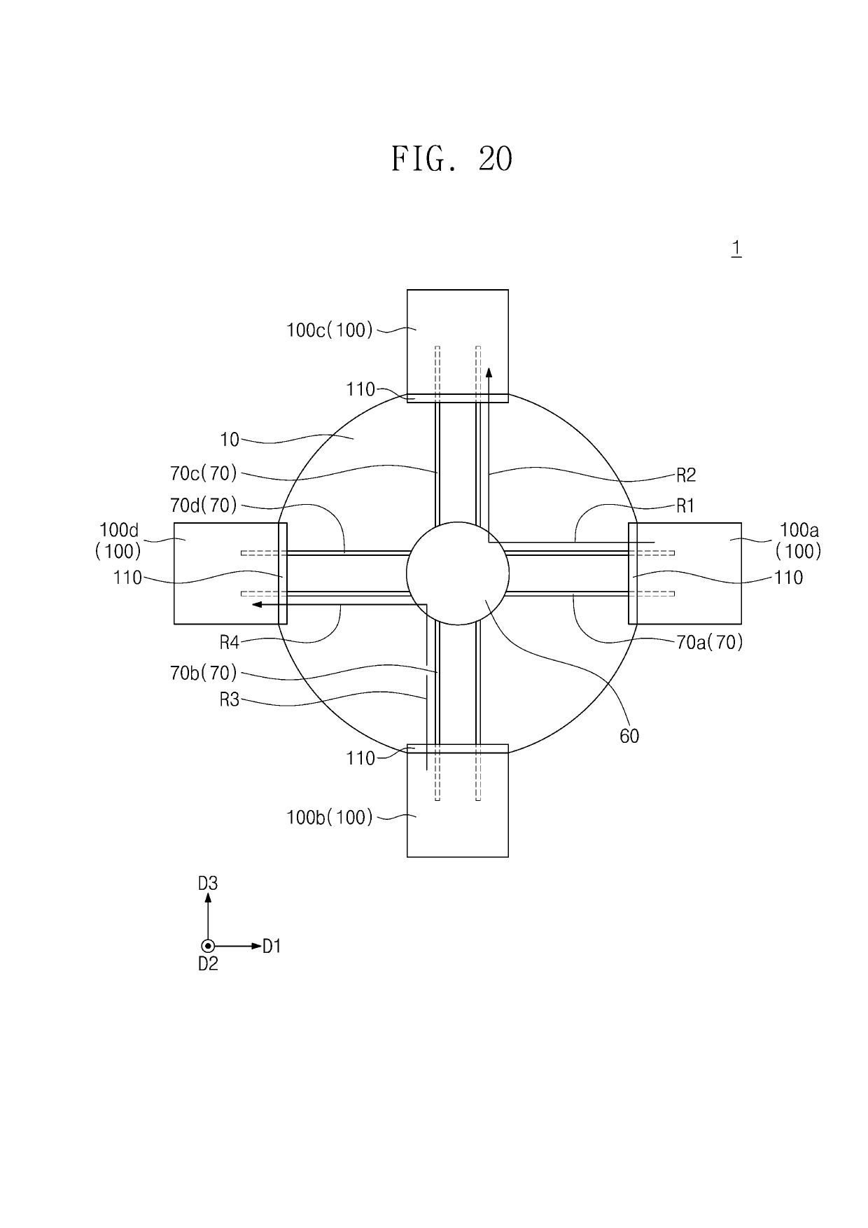

FIGS. 19 and 20 are plan views each illustrating a focused ion beam device according to some embodiments of the inventive concept.

Referring to FIGS. 19 and 20, unlike the described above, the loader 100 may include three or more loaders 100, and a rail 70 may include three or more rails 70.

Referring to FIG. 19, the loader 100 may include three loaders 100. The loader 100 may include a first loader 100a, a second loader 100b, and a third loader 100c that are spaced apart from each other and arranged.

The rail 70 may include a first rail 70a between the first loader 100a and the stage 60, a second rail 70b between the second loader 100b and the stage 60, and a third rail 70c between the third loader 100c and the stage 60. For example, the first rail 70a may connect the first loader 100a and the stage 60 with each other, the second rail 70b may connect the second loader 100b and the stage 60 with each other, and the third rail 70c may connect the third loader 100c and the stage 60 with each other.

As the above-described configurations of the focused ion beam device 1, in the preparing of the first analysis sample in S2a or the preparing of the second analysis sample in S2b, the first holder HL1 and the second holder HL2 may move along paths described below.

The first holder HL1 to which a sample SP is fixed may be loaded onto the first loader 100a, and the second holder HL2 to which a grid GR is fixed may be loaded onto the second loader 100b. The first holder HL1 may perform a movement R1 from the first loader 100a to the stage 60 via the first rail 70a. Thereafter, after the sampling process is completed, the first holder HL1 may perform a movement R2 to the third loader 100c via the third rail 70c and may be unloaded from the third loader 100c. After the first holder HL1 is performed the movement R2 to the third loader 100c via the third rail 70c, the second holder HL2 to which the grid GR is fixed perform a movement R3 from the second loader 100b to the stage 60 via the second rail 70b. After the milling process is completed, the second holder HL2 may perform a movement R4 to the third loader 100c via the third rail 70c and may be unloaded from the third loader 100c.

In summary, the first holder HL1 may have different loaders to be loaded and unloaded. Similarly, the second holder HL2 may have different loaders to be loaded and unloaded. The loaders to which the first holder HL1 and the second holder HL2 are loaded may be different, and the loaders to which the first holder HL1 and the second holder HL2 are unloaded may be the same.

Referring to FIG. 20, a loader 100 may include four loaders 100. The loader 100 may include a first loader 100a, a second loader 100b, a third loader 100c, and a fourth loader 100d that are disposed to be spaced apart from each other.

A rail 70 may include a first rail 70a between the first loader 100a and the stage 60, a second rail 70b between the second loader 100b and the stage 60, a third rail 70c between the third loader 100c and the stage 60, and a fourth rail 70d between the fourth loader 100d and the stage 60.

With the above-described configurations of the focused ion beam device 1, in the preparing of the first analysis sample in S2a or the preparing of the second analysis sample in S2b as described above, the first holder HL1 and the second holder HL2 may move along paths described below.

A first holder to which a sample is fixed may be loaded onto the first loader 100a, and a second holder to which a grid is fixed may be loaded onto the second loader 100b. The first holder may perform a movement R1 from the first loader 100a to the stage 60 via the first rail 70a. Thereafter, after the sampling process is completed, the first holder may perform a movement R2 to the third loader 100c via the third rail 70c and may be unloaded from the third loader 100c. After the first holder is moved to the third loader 100c via the third rail 70c in the movement R2, the second holder to which the grid GR is fixed may be moved to the stage 60 via the second rail 70b from the second loader 100b in the movement R3. After the milling process is completed, the second holder may be moved to the fourth loader 100d via the fourth rail 70d in a movement R4 and may be unloaded from the fourth loader 100d.

In summary, the first holder may have different loaders to be loaded and unloaded. For example, the first holder may be loaded into a loader and then unloaded into another loader. Similarly, the second holder HL2 may have different loaders to be loaded and unloaded. The loaders to which the first holder and the second holder are loaded may be different, and the loaders to which the first holder and the second holder are unloaded may also be different.

According to the inventive concept, the focused ion beam device may include the first loader and the second loader. Accordingly, the first holder for fixing the sample and the second holder for fixing the grid may move independently. As a result, the focused ion beam device may perform the process for producing the analysis sample (e.g., the proving process or the milling process, etc.) without the idle time even while replacing the sample with another sample. In addition, the focused ion beam device may perform the process for producing the analysis sample (e.g., the sampling process) without the idle time even while replacing the grid with another grid. Therefore, in the focused ion beam device and the method of producing the analysis sample the same, the productivity and efficiency may be improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A focused ion beam device comprising:
a chamber;
a stage in the chamber;
an electron beam generator in the chamber and emitting an electron beam toward a sample on the stage;
an ion beam generator in the chamber and emitting an ion beam toward the sample on the stage;
a detector in the chamber and detecting secondary electrons emitted from the sample; and
a first loader connected to the chamber and a second loader connected to the chamber.

2. The focused ion beam device of claim 1,
wherein the first loader is configured to load the sample, and
wherein the sample moves from the first loader to the stage.

3. The focused ion beam device of claim 1,
wherein the second loader is configured to load a grid.

4. The focused ion beam device of claim 1, further comprising:
a first rail connecting the first loader to the stage; and
a second rail connecting the second loader to the stage.

5. The focused ion beam device of claim 4,
wherein the first loader is configured to load the sample, and
wherein the first rail moves the sample from the first loader to the stage.

6. The focused ion beam device of claim 4,
wherein the second loader is configured to load a grid, and
wherein the second rail moves the grid from the second loader to the stage.

7. The focused ion beam device of claim 1,
wherein the second loader is configured to load a grid, when the sample is on the stage.

8. A focused ion beam device comprising:
a chamber provided with
an electron beam generator, an ion beam generator, and a detector;
a first loader connected to the chamber; and
a second loader connected to the chamber,
wherein the first loader is configured to load a first holder for fixing a sample, and
wherein the second loader is configured to load a second holder for fixing a grid.

9. The focused ion beam device of claim 8,
wherein the first loader is configured to move the first holder into the chamber.

10. The focused ion beam device of claim 8,
wherein the second loader is configured to move the second holder into the chamber.

11. The focused ion beam device of claim 8,
wherein the first loader and the second loader are configured such that the second holder is loaded on the second loader when the first holder moves into the chamber.

12. The focused ion beam device of claim 8,
wherein the first loader and the second loader are configured such that the first holder is loaded on the first loader when the second holder moves into the chamber.

13. A method of producing an analysis sample, the method comprising:
loading a first sample on a first loader of a focused ion beam device;
loading a first grid on a second loader of the focused ion beam device;
moving the first sample from the first loader into a chamber of the focused ion beam device;
performing a sampling process on the first sample to extract a first sample piece from the first sample;
moving the first grid from the second loader into the chamber;
fixing the first sample piece to the first grid; and
performing a milling process on the first sample piece.

14. The method of claim 13, further comprising:
moving the first sample from the chamber to the first loader, after the sampling process is performed on the first sample.

15. The method of claim 14,
wherein the moving of the first grid from the second loader into the chamber is performed, after the moving of the first sample from the chamber to the first loader.

16. The method of claim 14, further comprising:
replacing the first sample moved from the chamber to the first loader with a second sample during a time when the milling process is performed on the first sample piece.

17. The method of claim 16, further comprising:
moving the first grid to the second loader from the chamber, after the milling process is performed on the first sample piece; and
moving the second sample from the first loader into the chamber, after the moving of the first grid from the chamber to the second loader.

18. The method of claim 17, further comprising:
replacing the first grid with a second grid, after the moving of the second sample from the first loader into the chamber.

19. The method of claim 13, further comprising:
moving the first sample from the chamber to a third loader of the focused ion beam device, after the sampling process is performed on the first sample.

20. The method of claim 19, further comprising:
moving the first grid from the chamber to a fourth loader of the focused ion beam device, after the milling process is performed on the first sample piece.
